(19) United States
(12) Patent Application Publication
(10) Pub. No.: US 2018/0133636 A1
(43) Pub. Date: May 17, 2018

(54) FILTERING SYSTEM AND METHOD FOR INSTALLING THE SYSTEM ON AN HVAC OR COMPUTER SERVER CLOSET

(71) Applicant: BYRON RAPHAEL LALAMA, PLANTATION, FL (US)

(72) Inventor: BYRON RAPHAEL LALAMA, PLANTATION, FL (US)

(21) Appl. No.: 15/351,729

(22) Filed: Nov. 15, 2016

(51) Int. Cl. B01D 46/00; B01D 46/16; F24F 13/28; H05K 7/20

(52) U.S. Cl. CPC B01D 46/0005; B01D 46/0026; B01D 46/16; F24F 13/28; B01D 2279/50; H05K 7/20736; B01D 2265/06; B01D 2279/45; H05K 7/20181

(57) ABSTRACT

A filtering system and method for installing the system on an HVAC or computer server closet. The filtering system comprises of two horizontal rails and two vertical rails, the rails are secured together to form a rectangular structure. The rails define a channel on a front side of the rails. An air filtering screen that is placed over the front side of the rails. And, a slat that secures the air filter within the channel of the rails.

The present invention is directed at a filtering system and method for installing the system on an HVAC or computer server closet.

The present invention provides a filtering system to an HVAC or computer server that is not physically connected to the HVAC unit or the computer server.

The purpose of the present invention is to provide a filtering system that can be cleaned without having to remove a secondary filter from the HVAC unit or the computer server housing structure.

By providing the present filtering system to a closet, the owner of the HVAC unit prolongs the life of the filter physically attached to the HVAC unit or the computer server. The present system does this by capturing most of the dust particles that would normally pass through the HVAC unit prior to them reaching the HVAC or computer server filter. The frame of the filtering system of the present invention is fixedly installed on the borders of a closet. The frame defines a channel in which a rectangular filter is placed over and then a slat is forced within the channel so that the filter is held in place on the rails of the filtering system. The slat may be made of a rubber or silicon rope.

The present filtering system works by first filling a first area of the filter with dust particles and then the remaining areas. The first surface area of the filter is first filled with dust particles that are in the stream of air being pulled toward the intake of the HVAC unit or computer server. Upon the first are being filled or clogged with dust particles, the stream of air will be rerouted to a secondary area having a lesser resistance until there remains no filter area in which the stream of air can pass through cleanly. The filtering system of the present invention can be vacuumed clean periodically thereby providing maximum airflow efficiency.

U.S. Pat. No. 5,368,622, issued to McMillon On May 29, 1994 discloses some of the prior art with regards to filter and filter frames. The “622” patent does not disclose the present invention. The “622” patent describes a filter frame that is inserted within an HVAC unit and the need for the filter frame.

For the foregoing reasons, there is a need for a filtering system and it method of installation on a HVAC or computer server closet.

### SUMMARY

The present invention describes a filtering system and it method of installation on an HVAC or computer server closet. The filtering system comprises of a rail system that defines a channel on one of its sides of the rail system. An air filter screen that is placed over rail system so that all the channels of the rail system are covered by the air filter screen. And, a slat that secures the screen within the channel of the rail system.

An object of the present invention is to provide a filtering system that will prolong the life of an HVAC or computer server.

Another object of the present invention is to provide a filtering system that can be cleaned easily.

Yet another object of the present invention is to provide and air filter that is not attached or inserted within an HVAC unit that will prolong the life of the air filter attached to the HVAC unit or computer server.

Still a further object of the present invention is to provide an air filtering system that will enhance the air quality within a residential of commercial structure.

### DRAWINGS

These and other features, aspects, and advantages of the present invention will become better understood with regards to the following description, appended claims, and drawings where:

FIG. 1 is a front view of the filtering system showing how it is mounted on the inside of a door frame, the view shows the rail of the system;

FIG. 2 is an exploded view of a channel that is on the rail of the system;

FIG. 3 is a front view and an exploded view of the air filter screen that is placed on the rail system; and

FIG. 4 is an exploded view of how the slat is placed within the channel of the rails of the present invention. Note, the screen is not shown in the exploded view, yet when installing and using the system, the screen is secured within the channel by the slat.

### DESCRIPTION

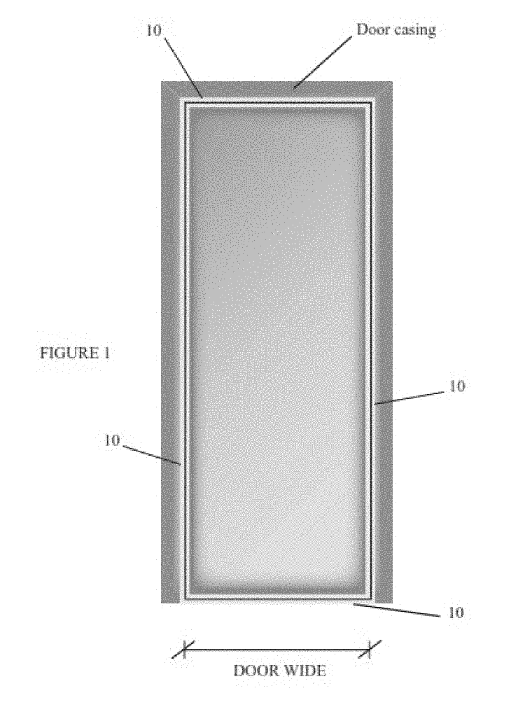

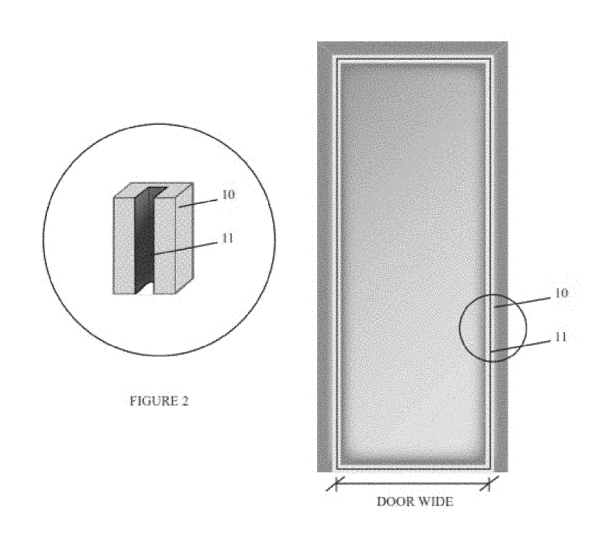

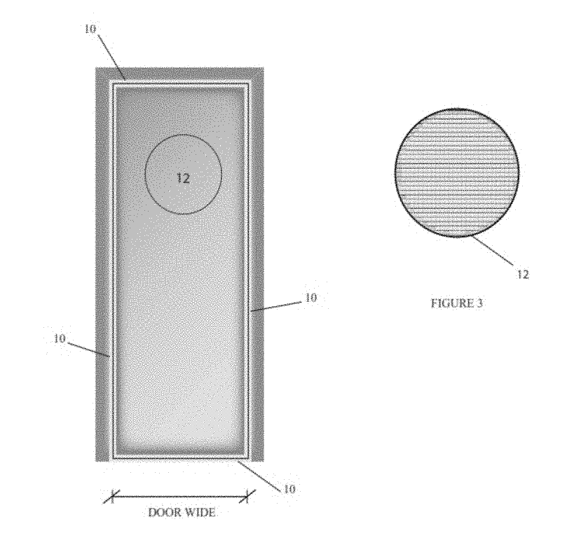

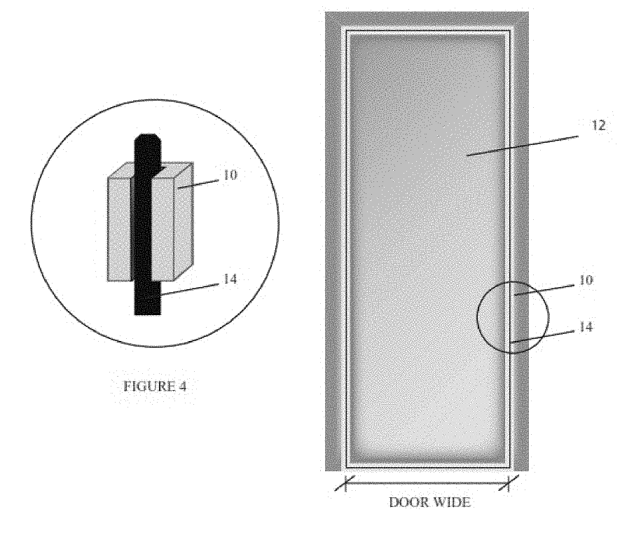

As seen in FIGS. 1-4, the present invention is directed to a filtering system and method for installing the system on an HVAC or computer server closet. The filtering system comprises of two horizontal rails 10 and two vertical rails 1, the rails are secured together to form a rectangular structure. The rails define a channel 11 on a front side of the rails 10. An air filtering screen 12 that is placed over the front side of the rails 10. And a slat 14 that secures the air filter 12 within the channel 11 of the rails 10.

The present invention is installed within the borders of an opening of a closet or similar structure. The closet has a top, bottom and two vertical sides. The horizontal rails are secured on the top and bottom sides of the closet so that the channels 11 of the rails 10 face outwardly from the closet. The vertical rails 10 are secured on the vertical sides of the closet so that the channels 11 of the rails 10 face outwardly from the closet. After the rails 10 are secured onto the closet, then an air filter screen 12 is placed over the channels 11 of all the rails 10. And lastly, a slat 14 is used to secure the air filter 12 on the rails 10, the slat 14 is inserted within the channels 11 thereby securing the air filter in a fixed position.

The rails 10 may be made of a plastic, a metal, a wood or aluminum.

The slat 14 can be a rubber cord or a silicon cord or any cord being composed or made of a similar material.

The air filter screen 12 can be made of any known material that can allow air to pass and that can withstand being vacuumed by a vacuum. In one embodiment, the screen is made of polyester. In an embodiment, the air filter screen may be a mesh.

An advantage of the present invention is that is provides a filtering system that prolongs the life of an HVAC or computer server.

Another advantage of the present invention is that it provides a filtering system that is easily cleaned.

Yet another advantage of the present invention is that it provides and air filter that is not attached or inserted within an HVAC unit that prolongs the life of the air filter attached to the HVAC unit or computer server.

Still a further advantage of the present invention is that it provides an air filtering system that enhances the air quality within a residential of commercial structure.

While the inventor's above description contains many specificities, these should not be construed as limitations on the scope, but rather as an exemplification of several preferred embodiments thereof. Many other variations are possible. For example, the rail system can be circular. Accordingly, the scope should be determined not by the embodiments illustrated, but by the appended claims and their legal equivalents.

What is claimed is:

1. A filtering system and method for installing the system on an HVAC or computer server closet, the filtering system comprises:
a pair of horizontal rails and a pair of vertical rails, the rails are secured together to form a rectangular structure, the rails define a channel on a front side of all of the rails;
an air filtering screen that is placed over the front side of the rails; and
a slat that secures the air filter within the channel of the rails.

2. The filtering system and method for installing the system on an HVAC or computer server closet of claim 1, wherein the slat is a cord.

3. The filtering system and method for installing the system on an HVAC or computer server closet of claim 2, wherein the rail is made of an aluminum material.

4. The filtering system and method for installing the system on an HVAC or computer server closet of claim 2, wherein the rail is made of a plastic material.

5. The filtering system and method for installing the system on an HVAC or computer server closet of claim 2, wherein the rail is made of a wood material.

6. The filtering system and method for installing the system on an HVAC or computer server closet of claim 2, wherein the air filter screen is a mesh.

7. A method of installing a filtering system on an HVAC or computer server closet, the method comprising:
Providing a closet having an opening and a border on the opening, the closet has a top, a bottom and two vertical sides;
Providing a pair of horizontal and a pair of vertical rails, the rails define a channel on a front side of the rails
Securing the horizontal rails on the top and bottom sides of the closet so that the channels of the rails face outwardly from the closet;
Securing the vertical rails on the vertical sides of the closet so that the channels of the rails face outwardly from the closet;
Placing an air filter screen is placed over the channels of all the rails; and
Securing the air filter screen on the rails using a slat, the slat is inserted within the channels of the rails thereby securing the air filter screen on the rail.
